(19) United States
(12) Patent Application Publication
(10) Pub. No.: US 2003/0205720 A1
(43) Pub. Date: Nov. 6, 2003

(54) High-resistivity metal in a phase-change memory cell

(76) Inventor: Chien Chiang, Fremont, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/421,071

(22) Filed: Apr. 22, 2003

Related U.S. Application Data
(62) Division of application No. 09/747,726, filed on Dec. 20, 2000.

(51) Int. Cl. H01L 29/74

(52) U.S. Cl. 257/153

(57) ABSTRACT

The invention relates to lower electrode in a chalcogenide memory device. The lower electrode is a metal compound that includes at least one of nitrogen and silicon. Embodiments include refractory meta nitride, a refractory metal silicon nitride, and refractory metal silicide.

### BACKGROUND OF THE INVENTION

1. Field of the Invention

The present invention relates to a phase-change memory device. More particularly, the present invention relates to a heater electrode in a chalcogenide memory cell. In particular, the present invention relates to a metal compound lower electrode.

2. Description of Related Art

As microelectronic technology progresses, the need has arisen for new data retention schemes. One such data retention scheme is the chalcogenide phase-change technology. Typically, a phase-change memory device includes a polysilicon lower electrode, also known as a “matchstick”.

After the formation of a recess in a substrate that exposes an active area, a conformal introduction of lower electrode material is required. Lower electrode material is typically polycrystalline silicon. The conformal introduction of lower electrode material that is polycrystalline silicon may follow conventional introduction techniques known to those skilled in the art including chemical vapor deposition (CVD) techniques. Thereafter, a dopant is introduced into the polycrystalline silicon to adjust the resistivity, in one aspect, to lower the resistivity of the material. A suitable dopant is a P-typed dopant such as boron introduced. From the combination of polysilicon and dopant, a silicidation process is required to form a silicide of the lower electrode. This process typically is a doping, a first anneal, a wet strip, and a second anneal.

After proper doping and fill into the trench, a planarization step is required to remove any horizontal component of the lower electrode. Thereafter, a modifier material must be introduced into a portion of the lower electrode material to combine and/or react with the lower electrode material near the top to form a different material. The modifier is introduced to raise the local resistance of the lower electrode material. By modifying a portion of the lower electrode material, the resistivity at that modified portion may be changed. Because the modifying material is of a higher resistivity, the lower electrode may not provide sufficiently suitable ohmic contact between the lower electrode and the volume of memory material for a desired application. In such cases, modifying material may be introduced into the lower electrode at a depth below the exposed surface of the lower electrode. For example, a lower electrode of polycrystalline silicon may have polycrystalline silicon at the exposed surface and a modifying material at a depth below the exposed surface. Additionally, barrier materials must be added to prevent cross-contamination between the chalcogenide material and the lower electrode. Typically, the formation of a barrier requires a nitridation process.

As can be seen with a polysilicon lower electrode, several processes must be carried out before addition of the chalcogenide memory cell.

### BRIEF DESCRIPTION OF THE DRAWINGS

In order that the manner in which the above-recited and other advantages of the invention are obtained, a more particular descriptions of the invention briefly described above will be rendered by reference to specific embodiments thereof which are illustrated in the appended drawings. Understanding that these drawings depict only typical embodiments of the invention that are not necessarily drawn to scale and are not therefore to be considered to be limiting of its scope, the invention will be described and explained with additional specificity and detail through the use of the accompanying drawings in which:

FIG. 1 is a schematic diagram of an array of memory elements according to an embodiment of the invention;

FIG. 2 schematically illustrates a cross-sectional planar side view of a portion of a semiconductor substrate having dielectric trenches formed therein defining a z-direction thickness of a memory cell in accordance with one embodiment of the invention of forming a memory element on a substrate;

FIG. 3 shows the structure of FIG. 2, through the same cross-sectional view, after the introduction of dopants to form an isolation device for a memory element in accordance with one embodiment of the invention;

FIG. 4 shows the structure of FIG. 3 after the introduction of a masking material over the structure in accordance with one embodiment of the invention;

FIG. 5 shows a schematic top view of the structure of FIG. 4.;

FIG. 6 shows the cross-section of the structure of FIG. 4 through line B-B′;

FIG. 7 shows the structure of FIG. 5, through the same cross-sectional view, after the patterning of the x-direction thickness of a memory cell, the introduction of a dopant between the cells, and the introduction of a dielectric material over the structure;

FIG. 8 shows the structure of FIG. 7, through the same cross-sectional view, after the formation of trenches through the dielectric material in accordance with one embodiment of the invention;

FIG. 9 shows the structure of FIG. 8, through the same cross-sectional view, after the introduction of an electrode material over the structure in accordance with one embodiment of the invention;

FIG. 10 shows the structure of FIG. 9, through the same cross-sectional view, after planarization;

FIG. 11 shows the structure of FIG. 10, through the same cross-sectional view, after the introduction of a volume of memory material and second conductors over the structure, in accordance with one embodiment of the invention;

FIG. 12 shows the structure of FIG. 11, through the same cross-sectional view, after the introduction of the dielectric material over the second conductor and a third conductor coupled to the first conductor in accordance with an embodiment of the invention; and

FIG. 13 shows a graphical representation of setting and resetting a volume of a phase change memory material in terms of temperature and time.

### DETAILED DESCRIPTION OF THE INVENTION

The invention relates to a memory device that is used with phase-change material to memorialize data storage. The device uses a lower electrode material that is a high resistivity metal compound. The high resistivity metal compound may be a refractory metal compound such as TaN, TiN, WN, TaSiN, TiSiN, WSiN, TaSi, TiSi, and WSi.

The following description includes terms, such as upper, lower, first, second, etc. that are used for descriptive purposes only and are not to be construed as limiting. The embodiments of an apparatus or article of the present invention described herein can be manufactured, used, or shipped in a number of positions and orientation. Reference will now be made to the drawings wherein like structures will be provided with like reference designations. In order to show the structures of the present invention most clearly, the drawings included herein are diagrammatic representations of integrated circuit structures. Thus, the actual appearance of the fabricated structures for example in a photomicrograph, may appear different while still incorporating the essential structures of the present invention. Moreover, the drawings show only the structures necessary to understand the present invention. Additional structures known in the art have not been included to maintain the clarity of the drawings.

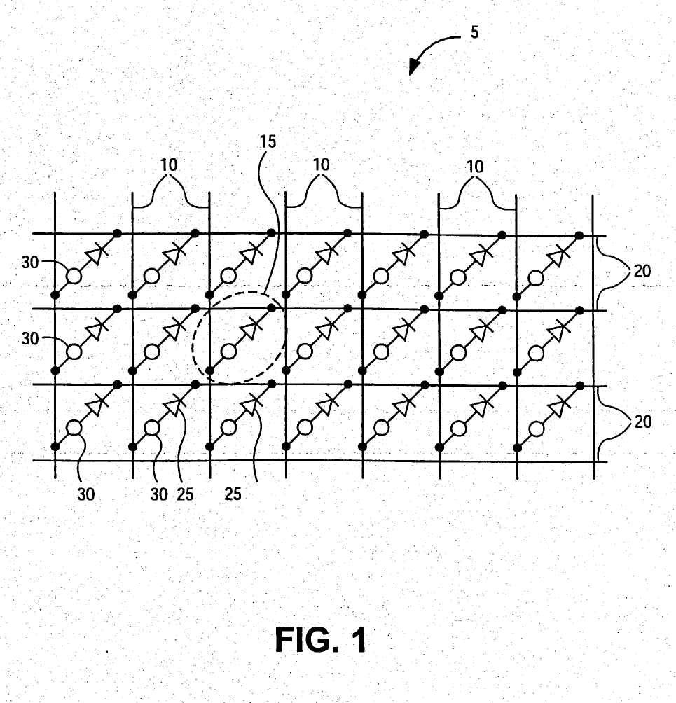

FIG. 1 shows a schematic diagram of an embodiment of a memory array comprised of a plurality of memory elements presented and formed in the context of the invention. In this example, the circuit of memory array 5 includes an array with memory element 30 electrically interconnected in series with isolation device 25 on a portion of a chip. Address lines 10 (e.g., columns) and 20 (e.g., rows) are connected, in one embodiment, to external addressing circuitry in a manner known to those skilled in the art. One purpose of the array of memory elements in combination with isolation devices is to enable each discrete memory element to be read and written without interfering with the information stored in adjacent or remote memory elements of the array.

A memory array such as memory array 5 may be formed in a portion, including the entire portion, of a substrate. A typical substrate includes a semiconductor substrate such as a silicon substrate. Other substrates including, but not limited to, substrates that contain ceramic material, organic material, or glass material as part of the infrastructure are also suitable. In the case of a silicon semiconductor substrate, memory array 5 may be fabricated over an area of the substrate at the wafer level and then the wafer may be reduced through singulation into discrete die or chips, some or all of the die or chips having a memory array formed thereon. Additional addressing circuitry such as sense amplifiers, decoders, etc. may be formed in a similar fashion as known to those of skill in the art.

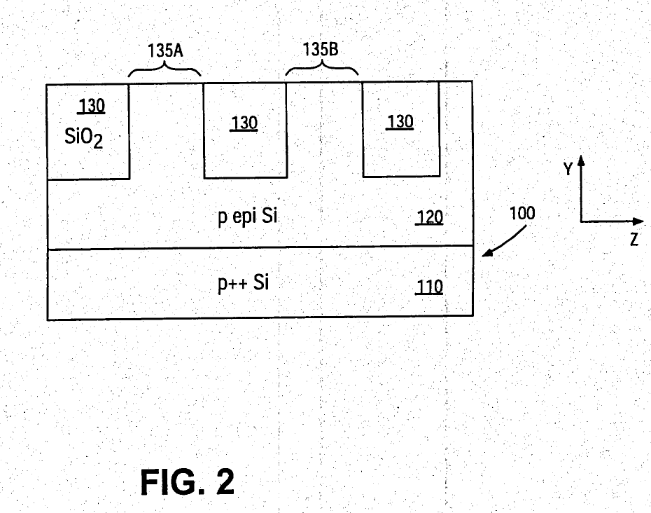

FIGS. 2-15 illustrate the fabrication of representative memory element 15 of FIG. 1. FIG. 2 shows a portion of substrate 100 that is, for example, a semiconductor substrate. In this example, a P-type dopant such as boron is introduced in a deep portion 110. In one example, a suitable concentration of P-type dopant is on the order of above 5×10¹⁹-1×10²⁰ atoms per cubic centimeters (atoms/cm³) rendering deep portion 110 of substrate 100 representatively P⁺⁺. Overlying deep portion 110 of substrate 100, in this example, is an epitaxial portion 120 of P-type epitaxial silicon. In one example, the dopant concentration in epitaxial portion 120 is on the order of about 10⁶-10¹⁷ atoms/cm³. The introduction and formation of epitaxial portion 120 as P-type, and deep portion 110 may follow techniques known to those of skill in the art.

FIG. 2 also shows first shallow trench isolation (STI) structures 130 formed in epitaxial portion 120 of substrate 100. As will become apparent in the subsequent discussion, STI structures 130 serve, in one aspect, to define the z-direction thickness of a memory element cell, with at this point only the z-direction thickness of a memory element cell defined. In another aspect, STI structures 130 serve to isolate individual memory elements from one another as well as associated circuit elements such as transistor devices formed in and on substrate 100. STI structures 130 are formed according to techniques known to those skilled in the art.

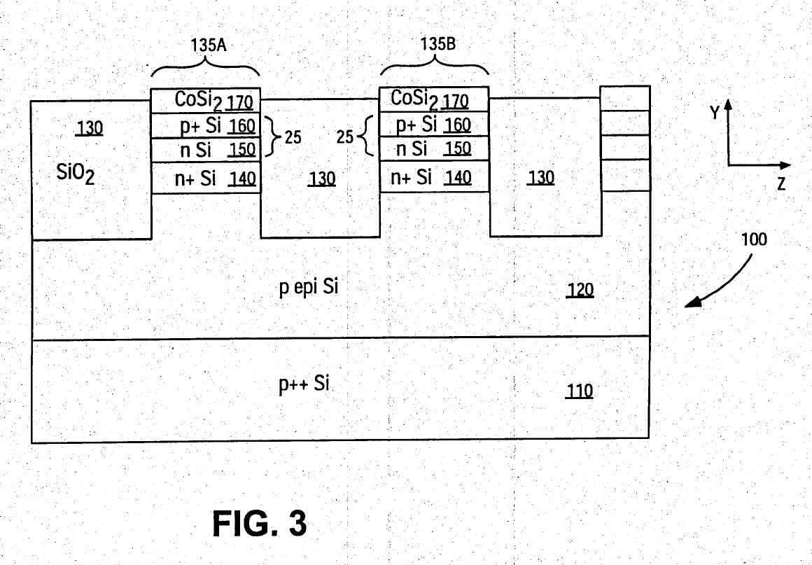

FIG. 3 shows the structure of FIG. 2 after a further fabrication operation in memory cell regions 135A and 135B. In one embodiment, memory cell regions 135A and 135B are introduced as strips with the x-direction dimension greater than the z-direction dimension. Overlying epitaxial portion 120 of substrate 100 is first conductor or signal line material 140. In one example, first conductor or signal line material 140 is N-type doped silicon formed by the introduction of, for example, phosphorous or arsenic to a concentration on the order of about 10¹⁸-10¹⁹ atoms/cm³ such as N⁺ silicon. In this example, first conductor or signal line material 140 serves as an address line, a row line such as row line 20 of FIG. 1. Overlying first conductor or signal line material 140 is an isolation device such as isolation device 25 of FIG. 1. In one example, isolation device 25 is a PN diode formed of N-type silicon portion 150 that may have a dopant concentration on the order of about 10¹⁷-10¹⁸ atoms/cm³ and P-type silicon portion 160 that may have a dopant concentration on the order of about 10¹⁹-10²⁰ atoms/cm³. Although a PN diode is shown, it is to be appreciated that other isolation structures are similarly suitable. Such isolation devices include, but are not limited to, MOS devices.

Referring to FIG. 3, overlying isolation device 25 in memory cell regions 135A and 135B is a reducer material 170 of, in this example, a refractory metal suicide such as cobalt silicide (CoSi₂). Reducer material 170, in one aspect, serves as a low resistance material in the fabrication of peripheral circuitry such as addressing circuitry of the circuit structure on the chip. Thus, reducer material 170 may not be required in terms of forming a memory element as described. Nevertheless, because of its low resistance property, its inclusion as part of the memory cell structure between isolation device 25 and memory element 30 is utilized in this embodiment. Additionally, because of its etch stop quality it eliminates additional lithography processes to mask it off from the memory cell.

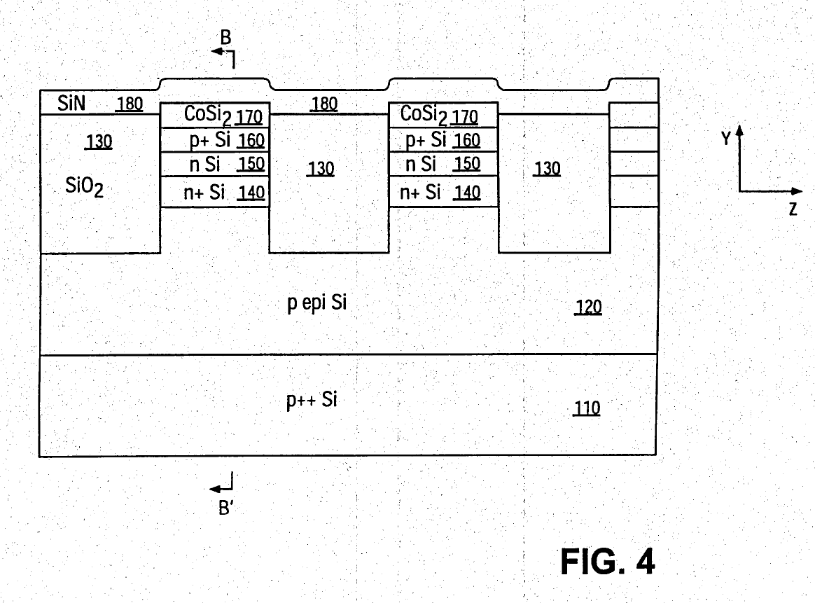

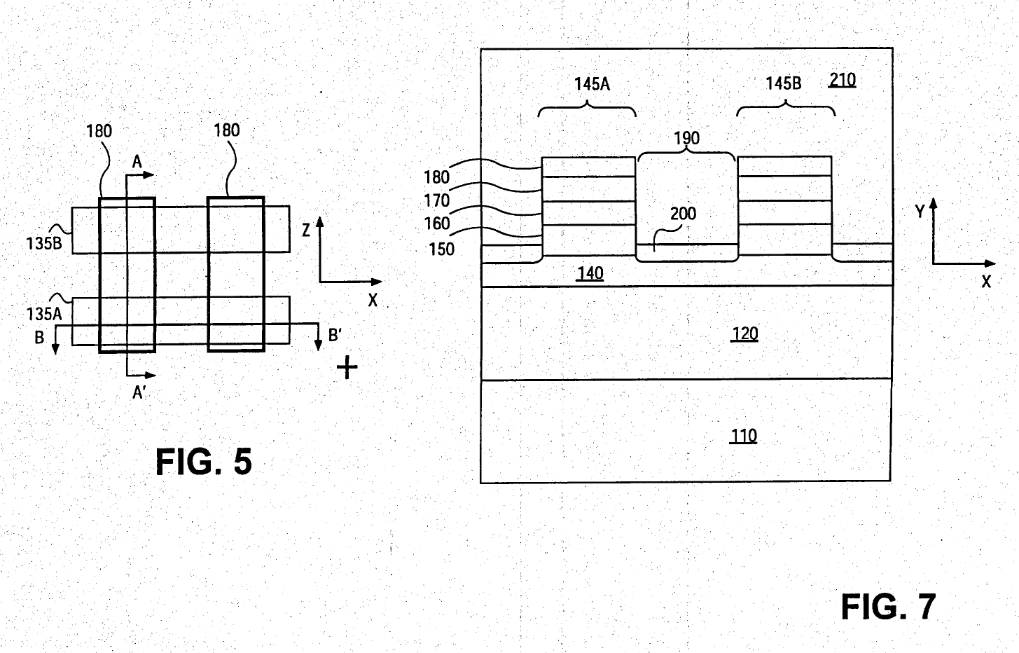

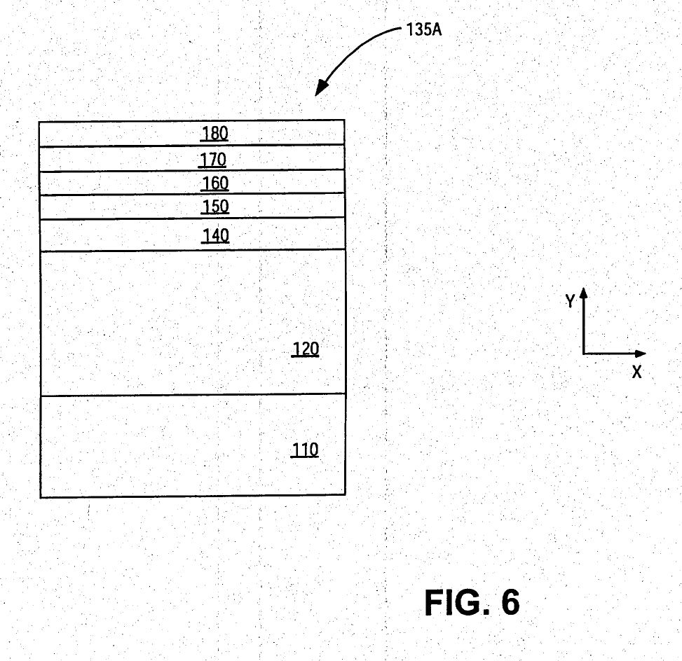

FIG. 4 shows the structure of FIG. 3 after the introduction of a masking material 180. As will become clear later, masking material 180 serves, in one sense, as an etch stop for a subsequent etch operation. FIG. 5 schematically shows memory cell regions 135A and 135B in an xz plane. Overlying the memory cell is masking material 180. FIG. 6 shows a cross-sectional side view of memory cell region 135A through line B-B′ of FIG. 5 in an xy perspective. In one embodiment, a suitable material for masking material 180 is a dielectric material such as silicon nitride (Si₃N₄) and the like although other materials may be used such as silicon oxy nitride (SiₓO_{y}N_{z}) in both stoichiometric and solid solution ratios.

FIG. 7 shows the structure of FIG. 6 from an xy perspective after patterning of the x-direction thickness of the memory cell material to form a trench 190. FIG. 7 shows two memory cells 145A and 145B patterned from memory cell region 135A depicted in FIG. 5. The patterning may be accomplished using conventional techniques for etching, in this example, refractory metal silicide and silicon material to, the exclusion of masking material 180. The definition of the x-direction thickness involves, in one embodiment, an etch to conductive material 150 (N-type silicon in this embodiment) of the memory line stack to define memory cells 145A and 145B of memory cell region 135A. In the case of an etch, the etch proceeds through the memory line stack to, in this example, a portion of a conductor or signal line that is in this case conductive material 150. A timed etch may be utilized to stop an etch at this point.

Following the patterning, N-type dopant is introduced at the base of each trench 190 to form pockets 200 having a dopant concentration on the order of about 10¹⁸-10²⁰ atoms/cm³ to form an N⁺ region between memory cells 145A and 145B. Pockets 200 serve, in one sense, to maintain continuity of a row line and to reduce the low resistance. Dielectric material 210 of, for example, silicon dioxide material is then introduced over the structure to a thickness on the order of 100 Å to 50,000 Å.

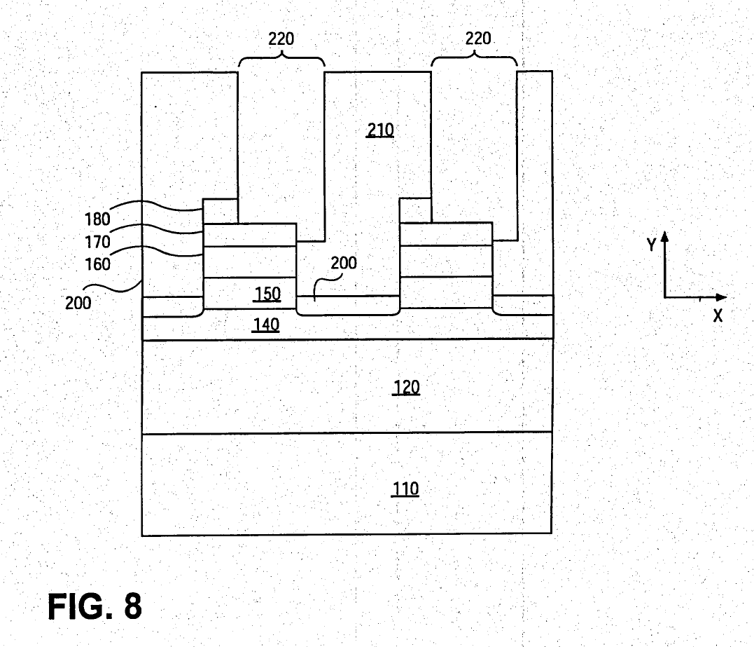

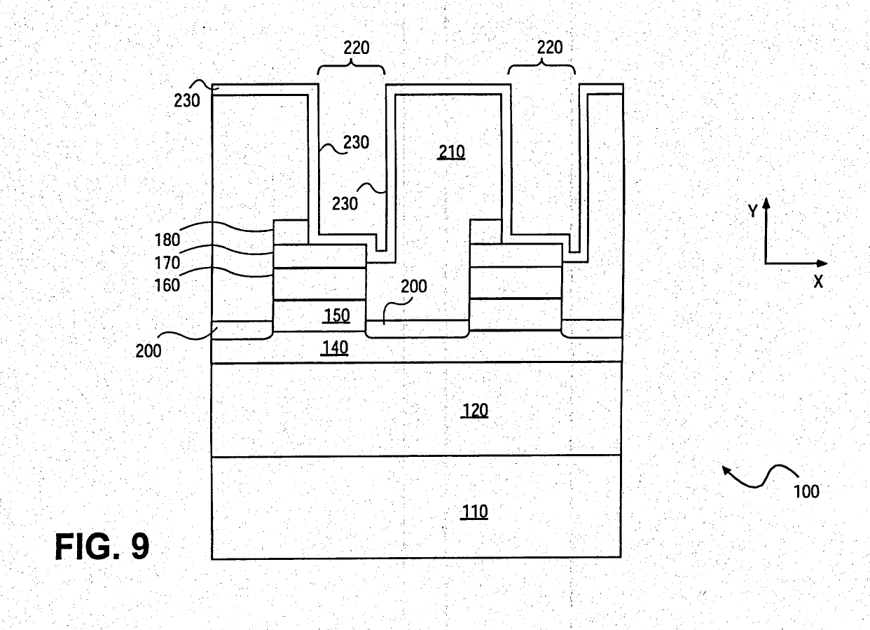

FIG. 8 shows the structure of FIG. 7 after the formation of trenches 220 through dielectric materials 210 and masking material 180 to reducer material 170. The formation of trenches 220 may be accomplished using etch patterning with an etchant(s) for etching dielectric materials 210 and 180 and selective to reducer material 170 such that reducer material 170 may serve as an etch stop. As such, dielectric material 210 forms what may be characterized as a container dielectric 210. Trench 220 may be referred to as a recess that is formed in first dielectric 210 to expose at least a portion of the memory cell stack as illustrated in FIG. 9. Although the recess is referred to as trench 220, the type of recess may be selected from a substantially circular recess, a rectangular (square) recess, and a trench recess.

FIG. 9 illustrates the inventive process of forming a lower electrode in a phase-change memory device by using the inventive metal compound film. The memory line stack may be referred to as an active area. FIG. 9 shows the structure of FIG. 8 after the conformal introduction of a lower electrode material 230 that may be referred to as a metal compound film.

The material of lower electrode material 230 is preferably a high resistivity metal compound such as metal nitride, a refractory metal nitride, a metal silicon nitride, a refractory metal silicon nitride, a metal silicide, and a refractory metal silicide. In one example, metal compound film 230 is a metal nitride compound such as tantalum nitride (TaₓN_{y}) that, depending upon the desired resistivity, may be provided in either stoichiometric or other metal compound film solid solution ratios.

The introduction is conformal in the sense that metal compound film 230 is introduced along the side walls and base of trench 220 such that metal compound film 230 is in contact with reducer material 170. The conformal introduction of metal compound film 230 that is the inventive metal nitride and/or silicide compound may follow conventional introduction techniques known to those skilled in the art including chemical vapor deposition (CVD) techniques.

Trench 220 may be referred to as a recess that is formed in first dielectric 210 to expose at least a portion of the memory cell stack as illustrated in FIG. 9. Although the recess is referred to as trench 220, the type of recess may be selected from a substantially circular recess, a rectangular (square) recess, and a trench recess.

Metal compound film 230 includes a metal and at least one of nitrogen or silicon. A given blend of metal compound may be accomplished by chemical vapor deposition (CVD) of at least one constituent of nitrogen and silicon in connection with the metal. Preferably, the composition of metal compound film 230 is controlled by feed stream amounts to a CVD tool. Depending upon the specific embodiment, other CVD techniques may be used such as plasma enhanced CVD (PECVD).

In another embodiment, the formation of metal compound film 230 is carried about by physical vapor deposition (PVD) and a target is selected that has a preferred composition for the final metal compound film. Alternatively, a plurality of targets may be combined to achieve a preferred metal compound film composition. In either PVD or CVD, coverage as defined as the ratio of wall deposited thickness to top-deposited thickness, is in a range from about 0.25 to about 1, and preferably above 0.5. In the present invention, CVD formation of lower electrode is preferred.

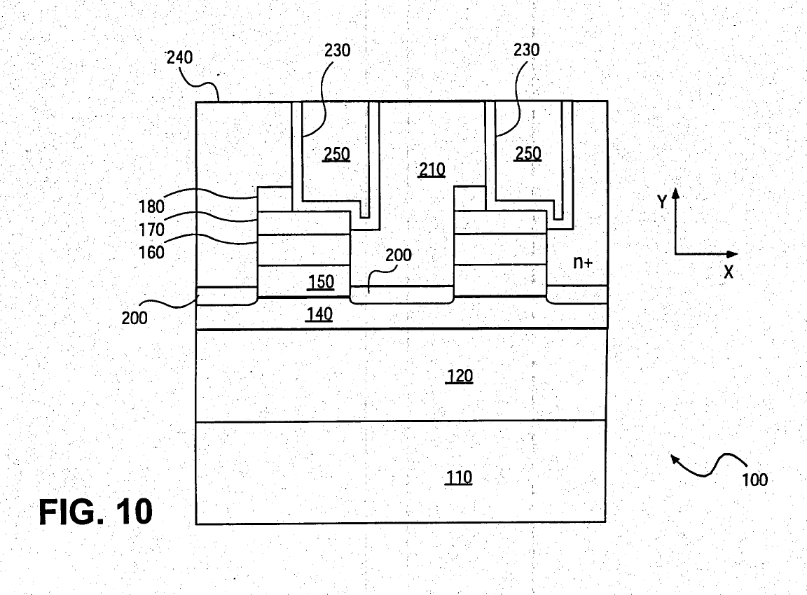

Following the formation of metal compound film 230, recess 220 is filled with a second dielectric 250. Second dielectric 250 may be formed by chemical vapor deposition of a silicon-containing substance selected from silicon oxide such a tetra ethyl ortho silicate (TEOS) process and the like. Following the formation of second dielectric 250, all material that resides above the top level 240 of recess is removed as illustrated in FIG. 10. Removal of material may be accomplished by processes such as chemical mechanical planarization (CMP), mechanical planarization, and the like. Removal of material may be accomplished by processes such as isotropic etchback, anisotropic etchback, and the like. In comparison to the formation of a polysilicon lower electrode process the inventive process reduces the complexity of the process flow.

The material of metal compound film 230 is preferably a high resistivity metal compound such as a metal nitride, a refractory metal nitride, a metal silicon nitride, a refractory metal silicon nitride, a metal silicide, and a refractory metal silicide.

Where a metal nitride is selected for metal compound film 230, the metal may be selected from Ti and Zr and the like. It may also be selected from Ta and Nb and the like. It may also be selected from W and Mo and the like. It may also be selected from Ni and Co and the like. The metal nitride is preferably a refractory metal nitride compound of the formula MₓN_{y}. The ratio of M:N is in a range from about 0.5:1 to about 5:1, preferably from about 0.6:1 to about 2:1, and most preferably about 1:1. For example, one embodiment of the present invention is a TₐN_{y} compound in the ratio from about 0.5:1 to about 5:1, preferably from about 0.6:1 to about 2:1, and most preferably about 1:1. Another example of an embodiment is a WₓN_{y} compound in the ratio from about 0.5:1 to about 5:1, preferably from about 0.6:1 to about 2:1, and most preferably about 1:1.

In another embodiment of the invention, metal compound film 230 may be a metal silicon nitride compound. The metals may be selected from the metal may be selected from Ti and Zr and the like. It may also be selected from Ta and Nb and the like. It may also be selected from W and Mo and the like. It may also be selected from Ni and Co and the like. The metal silicon nitride compound may have the formula MₓSi_{z}N_{y}, and wherein the ratio of M:Si:N is in a range from about 1:0.5:0.5 to about 5:1:1. Preferably, the ratio is in a range from about 1:1:0.5 to 1:0.5:1, and most preferably about 1:1:1. In one embodiment, a lower electrode material compound is TiₓSi_{y}N_{z} in a ratio from about 1:0.5:0.5 to about 5:1.1, preferably from about 1:1:0.5 to 1:0.5:1, and most preferably about 1:1:1.

In another embodiment, the lower electrode may be a metal silicide compound. The metals may be selected from the metal may be selected from Ti and Zr and the like. It may also be selected from Ta and Nb and the like. It may also be selected from W and Mo and the like. It may also be selected from Ni and Co and the like. The metal silicide compound may have the formula MₓSi_{z}, wherein the ratio of M:Si: is in a range from about 0.5:1 to about 5:1. In one embodiment, a lower electrode material compound is TiₓSi_{y} in a ratio from about 0.5:1 to about 5:1, preferably from about 0.6:1 to about 2:1, and most preferably about 1:1. In another embodiment, a lower electrode material compound is WₓSi_{y} in a ratio from about 0.5:1 to about 5:1, preferably from about 0.6:1 to about 2:1, and most preferably about 1:1.

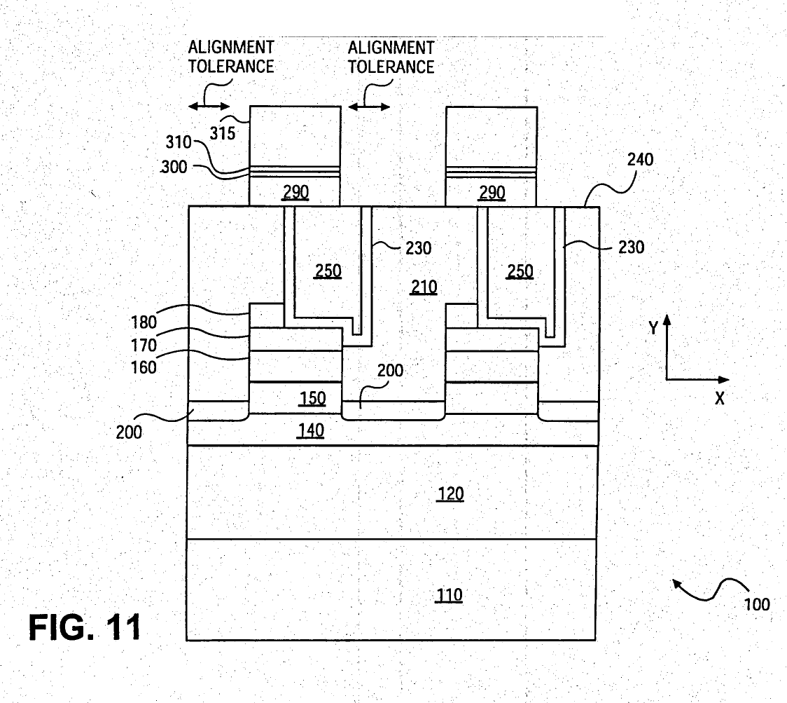

FIG. 11 shows the structure of FIG. 10 after the introduction of a volume of memory material 290 (represented as memory element 30 in FIG. 1). In one example, memory material 290 is a phase change material. In a more specific example, memory material 290 includes a chalcogenide element(s). Examples of phase change memory material 290 include, but are not limited to, compositions of the class of tellerium-germanium-antimony (TeₓGe_{y}Sb_{z}) material in both stoichiometric and solid-solution ratios. The volume of memory material 290, in one example according to current technology, is introduced and patterned with a thickness on the order of about 600 Å.

Overlying the volume of memory material 290 in the structure of FIG. 11 are barrier materials 300 and 310 of, for example, titanium (Ti) and titanium nitride (TiN), respectively. Barrier material serves, in one aspect, to inhibit diffusion between the volume of memory material 290 and second conductor or signal line material overlying the volume of memory material 290 (e.g., second electrode 10). Overlying barrier materials 300 and 310 is second conductor or signal line material 315. In this example, second conductor or signal line material 315 serves as an address line, a column line (e.g., column line 10 of FIG. 1). Second conductor or signal line material 315 is patterned to be, in one embodiment, generally orthogonal to first conductor or signal line material 140 (column lines are orthogonal to row lines). Second conductor or signal line material 315 is, for example, an aluminum material, such as an aluminum alloy. Methods for the introduction and patterning of the barrier materials and second conductor or signal line material 315 include such techniques as known to those of skill in the art.

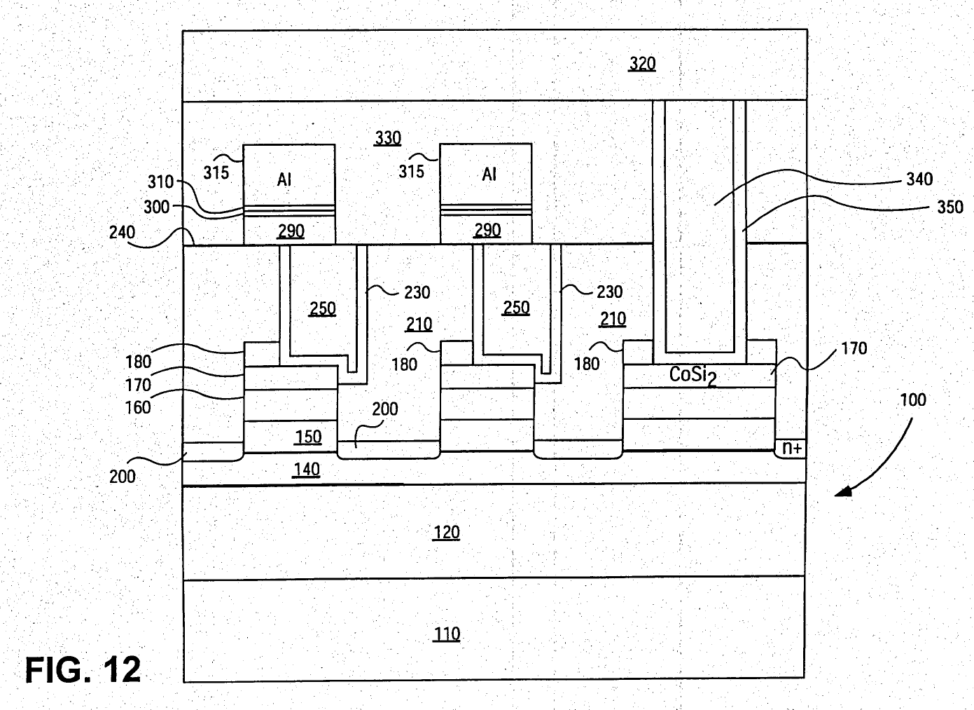

FIG. 12 shows the structure of FIG. 11 after the introduction of dielectric material 330 over second conductor or signal line material 315. Dielectric material 330 is, for example, SiO₂ or other suitable material that surrounds second conductor or signal line material 315 and memory material 290 to electronically isolate such structure. Following introduction, dielectric material 330 is planarized and a via is formed in a portions of the structure through dielectric material 330, dielectric material 210, and masking material 180 to reducer material 170. The via is filled with conductive material 340 such as tungsten (W) and barrier material 350 such as a combination of titanium (Ti) and titanium nitride (TiN). Techniques for introducing dielectric material 330, forming and filling conductive vias, and planarizing are known to those skilled in the art.

The structure shown in FIG. 12 also shows additional conductor or signal line 320 introduced and patterned to mirror that of first conductor or signal line material 140 (e.g., row line) formed on substrate 100. Mirror conductor line material 320 mirrors first conductor or signal line material 140 and is coupled to first conductor or signal line material 140 through a conductive via. By mirroring a doped semiconductor such as N-type silicon, mirror conductor line material 320 serves, in one aspect, to reduce the resistance of conductor or signal line material 140 in a memory array, such as memory array 5 illustrated in FIG. 1. A suitable material for mirror conductor line material 320 includes an aluminum material, such as aluminum or an aluminum alloy.

In the above description of forming a memory element such as memory element 15 in FIG. 1, metal compound film 230 is an electrode and is described between a memory material and conductors or signal lines (e.g., row lines and column lines) that has improved electrical characteristics. In the embodiment described, the resistivity of the electrode is selected to make a given metal compound film 230 as set forth herein. In this manner, a supplied voltage from second conductor or signal line material 320 or first conductor or signal line material 140 to the memory material 290 may be near the volume of memory material 290 and dissipation of energy to cause a phase change may be minimized. The discussion detailed the formation of one memory element of memory array 5. Other memory elements of memory array 5 may be fabricated in the same manner. It is to be appreciated that many, and possibly all, memory elements of memory array 5, along with other integrated circuit circuitry, may be fabricated simultaneously.

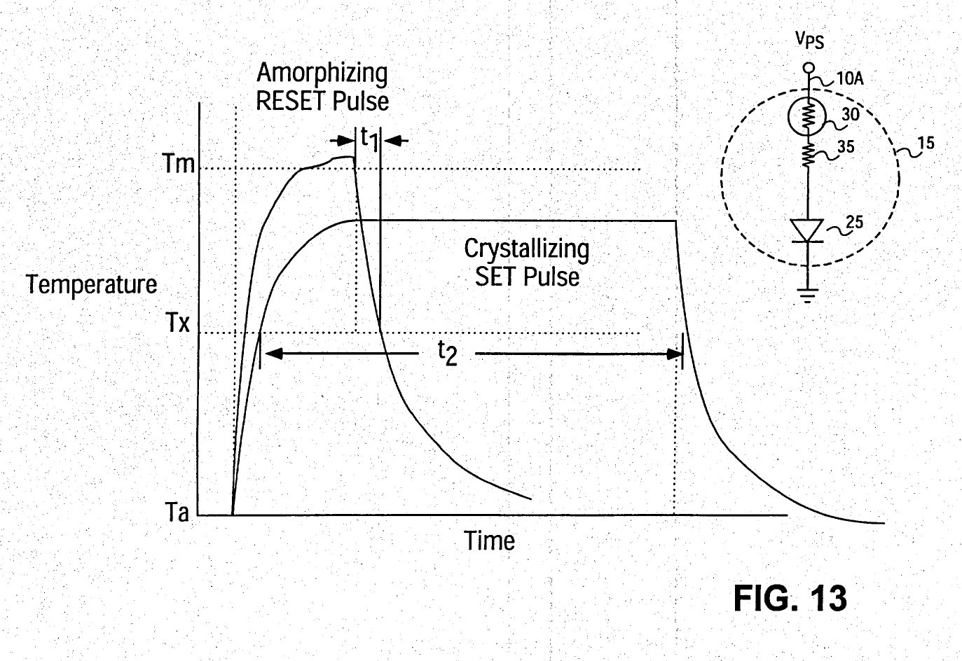

FIG. 13 presents a graphical representation of the setting and resetting of a volume of phase change memory material. Referring to FIG. 1, setting and resetting memory element 15 (addressed by column line 10a and row line 20a) involves, in one example, supplying a voltage to column line 10a to introduce a current into the volume of memory material 30 as illustrated in FIG. 1 or memory material 290 as illustrated in FIG. 12. The current causes a temperature increase at the volume of memory material 30. Referring to FIG. 13, to amorphize a volume of memory material, the volume of memory material is heated to a temperature beyond the amorphisizing temperature, T_{M}. Once a temperature beyond T_{M} is reached, the volume of memory material is quenched or cooled rapidly (by removing the current flow). The quenching is accomplished at a rate, t₁, that is faster than the rate at which the volume of memory material 30 can crystallize so that the volume of memory material 30 retains its amorphous state. To crystallize a volume of memory material 30, the temperature is raised by current flow to the crystallization temperature for the material and retained at that temperature for a sufficient time to crystallize the material. After such time, the volume of memory material is quenched (by removing the current flow).

In each of these examples of resetting and setting a volume of memory material 30, the importance of concentrating the temperature delivery at the volume of memory material 30 is illustrated. One way this is accomplished is modifying a portion of the electrode as described above. The inset of FIG. 13 shows memory cell 15 having an electrode with modified portion 35 (illustrated as a resistor) to concentrate heat (current) at the volume of memory material 30.

In the preceding example, the volume of memory material 30 was heated to a high temperature to amorphisize the material and reset the memory element (e.g., program 0). Heating the volume of memory material to a lower crystallization temperature crystallizes the material and sets the memory element (e.g., program 1). It is to be appreciated that the association of reset and set with amorphous and crystalline material, respectively, is a convention and that at least an opposite convention may be adopted. It is also to be appreciated from this example that the volume of memory material 30 need not be partially set or reset by varying the current flow and duration through the volume of memory material.

Because the contact between lower electrode upper surface 240 and the memory material 290 is a metal-to-metal interface, a lower interface resistance may exist that that of a doped polysilicon-chalcogenide interface.

Because of the chemical makeup of the inventive metal compound film 230 that forms the lower electrode, process flow is simplified. For example, implanting polysilicon and activating it is not required in t he process flow. A doped polysilicon lower electrode requires processing such as a doping process, an anneal process to activate the doped electrode to make it conductive, a barrier layer between the lower electrode upper surface, and processing to compositionally modify the upper surface for an enhanced heating at the upper surface.

In contrast, the inventive lower electrode is formed of metal compound film 230 and dielectric material is filled next to it. Thereafter, CMP is carried out and the memory material 290 material may be deposited.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. A process of forming a lower electrode in a phase-change memory device, comprising:
providing a substrate comprising an active area and a first dielectric;
forming a recess in the first dielectric to expose the active area;
depositing a metal compound film in the recess, wherein the metal compound includes at least one of nitrogen or silicon;
filling the recess with a second dielectric; and
removing the second dielectric located above the recess.

2. The process according to claim 1, wherein the metal compound film is selected from a metal nitride, a refractory metal nitride, a metal silicon nitride, a refractory metal silicon nitride, a metal silicide, and a refractory metal silicide.

3. The process according to claim 1, wherein the metal compound film is selected from a metal nitride, a refractory metal nitride, a metal silicon nitride, a refractory metal silicon nitride, a metal silicide, and a refractory metal silicide and wherein, forming a recess further comprises:
etching the recess, Wherein the recess is selected from a substantially circular recess, a rectangular recess, and a trench recess.

4. The process according to claim 1, wherein the metal compound film is selected from a metal nitride, a refractory metal nitride, a metal silicon nitride, a refractory metal silicon nitride, a metal silicide, and a refractory metal silicide, and wherein, forming a recess further comprises:
etching the recess with an etch recipe that is selective to metal silicide material and less selective to dielectric material.

5. The process according to claim 1, wherein the metal compound film is selected from a metal nitride, a refractory metal nitride, a metal silicon nitride, a refractory metal silicon nitride, a metal silicide, and a refractory metal silicide, and wherein depositing a metal compound film further comprises:
chemical vapor deposition of at least one of nitrogen and silicon in connection with the metal, wherein the metal compound film composition is controlled by feed stream amounts.

6. The process according to claim 1, wherein the metal compound film is selected from a metal nitride, a refractory metal nitride, a metal silicon nitride, a refractory metal silicon nitride, a metal silicide, and a refractory metal silicide, and wherein depositing a metal compound film further comprises:
chemical vapor deposition of at least one of nitrogen and silicon in connection with the metal, wherein the metal compound film composition is controlled by feed stream amounts, and wherein coverage is in a range from about is in a range from about 0.25 to about 1.

7. The process according to claim 1, wherein the metal compound film is selected from a metal nitride, a refractory metal nitride, a metal silicon nitride, a refractory metal silicon nitride, a metal silicide, and a refractory metal silicide, and wherein depositing a metal compound film further comprises:
physical vapor deposition.

8. The process according to claim 1, wherein filling the recess with a second dielectric further comprises:
chemical vapor deposition of a silicon-containing substance selected from silicon oxide, TEOS, BPSG, and BSG.

9. The process according to claim 1, wherein removing the second dielectric located above the recess further comprises:
planarizing by a process selected from mechanical planarizing, chemical mechanical planarizing, and anisotropic etch back.

10. The process according to claim 1, further comprising:
forming a phase-change memory material over the metal compound film.

11. The process according to claim 1, wherein the metal compound film is selected from tantalum nitride, tungsten nitride, titanium silicon nitride, titanium silicide, and tungsten silicide.

12. A lower electrode in a phase-change memory device comprising:
a substrate including an active area;
a recess in the substrate that communicates to the active area;
a metal compound film disposed in the recess, wherein the metal compound film is in contact with the active area, wherein the metal compound film extends to the top of the recess; and
wherein the metal compound includes at least one of nitrogen and silicon.

13. The lower electrode according to claim 12, wherein the metal compound is a refractory metal nitride compound.

14. The lower electrode according to claim 12, wherein the metal compound is a refractory metal nitride compound of the formula MₓN_{y}, and wherein the ratio of M:N is in a range from about 0.5:1 to about 5:1.

15. The lower electrode according to claim 12, wherein the metal compound is a refractory metal silicon nitride compound.

16. The lower electrode according to claim 12, wherein the metal compound is a refractory metal silicon nitride compound of the formula MₓSi_{z}N_{y} and wherein the ratio of M:Si:N is in a range from about 1:0.5:0.5 to about 5:1:1.

17. The lower electrode according to claim 12, wherein the metal compound is a refractory metal silicide compound.

18. The lower electrode according to claim 12, wherein the metal compound is a metal silicide compound of the formula MₓSi_{z}, and wherein the ratio of M:Si: is in a range from about 0.5:1 to about 5:1.

19. The process according to claim 12, wherein the metal compound film is tantalum nitride.

20. The process according to claim 12, wherein the metal compound film is tungsten nitride.

21. The process according to claim 12, wherein the metal compound film is titanium silicon nitride.

22. The process according to claim 12, wherein the metal compound film is titanium silicide.

23. The process according to claim, 2, wherein the metal compound film is tungsten silicide.

24. A lower electrode in a phase-change memory cell, comprising:
a plurality of memory cells;
a row select line; a column select line;
a phase-change memory material;
a lower electrode, the lower electrode further comprising:
a metal selected from titanium, zirconium, hafnium, vanadium, niobium, tantalum, chromium, molybdenum, tungsten, cobalt, nickel, tantalum, niobium, tungsten, cobalt, nickel an palladium;
nitrogen; and
optionally silicon.

25. The lower electrode according to claim 24, wherein the lower electrode is a refractory metal nitride compound of the formula MₓN_{y}, and wherein the ratio of M:N is in a range from about 0.5:1 to about 5:1.

26. The lower electrode according to claim 24, wherein the lower electrode is a metal silicon nitride compound of the formula MₓSi_{z}N_{y}, and wherein the ratio of M:Si:N is in a range from about 1:0.5:.0.5 to about 5:1:1.

27. The lower electrode according to claim 24, wherein the lower electrode is a refractory metal silicon nitride compound of the formula MₓSi_{z}N_{y}, and wherein the ratio of R:Si:N is in a range from about 1:0.5:0.5 to about 5:1:1;

28. The lower electrode according to claim 24, wherein the lower electrode is a metal silicide compound of the formula MₓSi_{z}, and wherein the ratio of M:Si: is in a range from about 0.5:1 to about 5:1.
